(19) United States
(12) Patent Application Publication
(10) Pub. No.: US 2012/0032351 A1
(43) Pub. Date: Feb. 9, 2012

(54) SEMICONDUCTOR PACKAGE

(76) Inventors: Chung-Yao KAO, Kaohsiung City (TW); Yu-Ju Li, Niaosong Township (TW); Chen-Ming Lai, Tainan City (TW); Cheng-Chiang Chen, Donggang Township (TW)

(21) Appl. No.: 12/943,491

(22) Filed: Nov. 10, 2010

(30) Foreign Application Priority Data
Aug. 5, 2010 (TW) 99126161

(51) Int. Cl. H01L 23/52

(52) U.S. Cl. 257/782; 257/E23.141

(57) ABSTRACT

A semiconductor package is provided. The semiconductor package includes a substrate, a semiconductor device, a plurality of element contacts, a molding compound and a plurality of substrate contacts. The substrate has opposite to the first surface the first surface and the second surface. The semiconductor device is disposed on the first surface. The element contacts electrically connect the substrate and the semiconductor device. The molding compound encapsulates the semiconductor device and a portion of the molding compound is located between the semiconductor device and the first surface, wherein the molding compound includes a plurality of fillers, the fillers amount to 85-89% of the molding compound and the sizes of the fillers range between 18 and 23 micrometers. The substrate contacts are formed on the second surface.

This application claims the benefit of Taiwan application Serial No. 99126161, filed Aug. 5, 2010, the subject matter of which is incorporated herein by reference.

### BACKGROUND OF THE INVENTION

1. Field of the Invention

The invention relates in general to a semiconductor package, and more particularly to a semiconductor package in which the space between the semiconductor device and the substrate is filled with a molding compound.

2. Description of the Related Art

FIG. 1 is a cross-sectional view of a conventional semiconductor package. The semiconductor package 10 includes a substrate 12, a flip chip 14 and an underfill layer 20. The underfill layer 20 is interposed between the flip chip 14 and the substrate 12 to encapsulate the solder balls 18 of the flip chip 14 so that the flip chip 14 is steady bonded on the substrate 12.

However, since the underfill layer 20 only contacts the bottom surface 16 of the flip chip 14, the bonding strength between the flip chip 14 and the substrate 12 is within limits and need to be further improved.

### SUMMARY OF THE INVENTION

The invention is related to a semiconductor package. A portion of molding compound is located between the semiconductor device and the substrate. The molding compound has high bonding strength, so that the bonding between the semiconductor device and the substrate is enhanced.

According to a first aspect of the present invention, semiconductor package. The semiconductor package includes a substrate, a semiconductor device, a plurality of element contacts, a molding compound and a plurality of substrate contacts. The substrate has a first surface and a second surface opposite to the first surface. The semiconductor device is disposed on the first surface. The element contacts electrically connect the substrate and the semiconductor device. The molding compound encapsulates the semiconductor device and a portion of the molding compound is located between the semiconductor device and the first surface, wherein the molding compound includes a plurality of fillers, the fillers amount to 85-89% of the molding compound and the sizes of the fillers range between 18 and 23 micrometer (μm). The substrate contacts are formed on the second surface.

According to a second aspect of the present invention, a semiconductor package is provided. The semiconductor package includes a substrate, a semiconductor device, a plurality of element contacts, a molding compound and a plurality of substrate contacts. The substrate has a first surface and a second surface opposite to the first surface. The semiconductor device is disposed on the first surface. The element contacts electrically connect the substrate and the semiconductor device. The molding compound encapsulates the semiconductor device and a portion of the molding compound is located between the semiconductor device and the first surface, wherein the low temperature CTE of the molding compound ranges between 8 and 10 (10⁻⁶/° C.). The substrate contacts are formed on the second surface.

According to a third aspect of the present invention, a semiconductor package is provided. The semiconductor package includes a substrate, a semiconductor device, a plurality of element contacts, a molding compound and a plurality of substrate contacts. The substrate has a first surface and a second surface opposite to the first surface. The semiconductor device is disposed on the first surface. The element contacts electrically connect the substrate and the semiconductor device. The molding compound directly contacts and encapsulates the semiconductor device and the element contacts, wherein the molding compound includes a plurality of fillers which amounts to 85-89% of the molding compound and the sizes of the fillers range between 18 and 23 μm. The substrate contacts are formed on the second surface.

According to a fourth aspect of the present invention, a semiconductor package is provided. The semiconductor package includes a substrate, a semiconductor device, a plurality of element contacts, a molding compound and a plurality of substrate contacts. The substrate has a first surface and a second surface opposite to the first surface. The semiconductor device is disposed on the first surface. The element contacts electrically connect the substrate and the semiconductor device. The molding compound directly contacts and encapsulates the semiconductor device and the element contacts, wherein the low temperature CTE of the molding compound ranges between 8 and 10. The substrate contacts are formed on the second surface.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of a conventional semiconductor package; and

FIG. 2 shows a cross-sectional view of a semiconductor package according to a preferred embodiment of the invention.

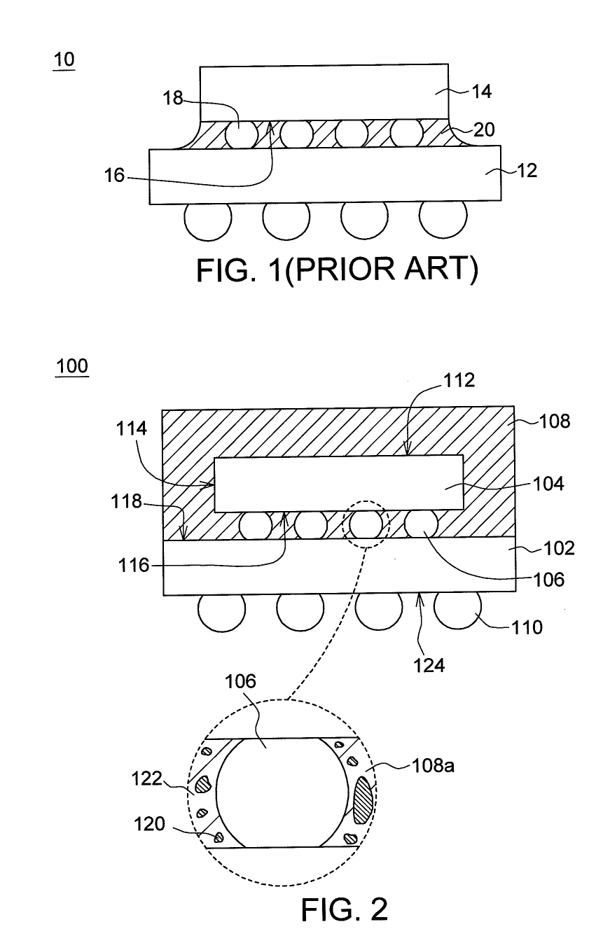

### DETAILED DESCRIPTION OF THE INVENTION

FIG. 2 is a cross-sectional view of a semiconductor package according to a preferred embodiment of the invention. The semiconductor package 100, such as a flip-chip chip scale package (FCCSP), includes a substrate 102, a semiconductor device 104, a plurality of element contacts 106, a molding compound 108 and a plurality of substrate contacts 110.

The substrate 102 has a first surface 118 and a second surface 124 opposite to the first surface. The semiconductor device 104, such as a flip chip, is disposed on the first surface 118. The substrate contacts 110, such as solder balls, conductive pillars and bumps, are formed on the second surface 124 of the substrate 102 for electrically connecting an external circuit (not illustrated) and the semiconductor package 100.

The element contacts 106, such as solder balls, bumps and conductive pillars, are disposed between the substrate 102 and the semiconductor device 104 for electrically connecting the substrate 102 and the semiconductor device 104.

The molding compound 108 directly contacts and covers a top surface 112 and a lateral surface 114 of the semiconductor device 104. The space between a bottom surface 116 of the semiconductor device 104 and the first surface 118 of the substrate 102 is filled with a portion of 108a of the molding compound 108, and covers the bottom surface 116, the first surface 118 and the element contacts 106. Thus, almost the entire semiconductor device 104 is tightly encapsulated by the molding compound 108.

The molding compound 108 includes a resin 122 and a plurality of fillers 120, wherein the fillers 120 amounts to 85-89% of the molding compound 108 and the sizes of the fillers 120 range between 18 and 23 μm. In comparison to the fillers of a conventional molding compound, the fillers 120 of the present embodiment of the invention have smaller sizes and the molding compound 108 has compact structure for increasing the structural strength of the molding compound 108. Accordingly, a portion 108a of the molding compound 108 is located between the semiconductor device 104 and the substrate 102 for increasing the bonding strength between the semiconductor device 104 and the substrate 102.

In comparison to the conventional semiconductor device, the material disposed between the semiconductor device 104 and the substrate 102 and the material encapsulating the semiconductor device 104 are the same in the present embodiment of the invention (that is, the molding compound 108). Thus, the material encapsulating the entire semiconductor device 104 has a uniform coefficient of thermal expansion (CTE) so that the warpage of semiconductor package 100 is reduced.

The molding compound 108 of the present embodiment of the invention replaces the underfill layer that is located between the semiconductor device 104 and the substrate 102. The manufacturing process of the semiconductor package 100 can remove the step of filling the underfill material, and therefore both of the manufacturing cost is reduced and manufacturing speed of the semiconductor package 100 is increased.

Though the properties of the molding compound are exemplified by its proportion and the size of the filler, the invention is not limited thereto. In an embodiment, the molding compound 108 may possess other properties and still can be interposed between the semiconductor device 104 and the substrate 102. For example, the spiral flow length of the molding compound 108 roughly ranges between 120 and 160 centimeters (cm), wherein the spiral flow length denotes the liquidity when the molding compound 108 is in a colloidal state. Or, the gelatin time of the molding compound 108 ranges between 40 and 60 seconds. Or, the low temperature coefficient of thermal expansion (CTE) of the molding compound 108 roughly ranges between 8 and 10 (10⁻⁶/° C.), wherein the low temperature CTE denotes the CTE of the molding compound 108 when the withstanding temperature of the molding compound 108 is lower than the glass transition temperature of the molding compound 108. Or, the high temperature CTE of the molding compound 108 roughly ranges between 33 and 43 (10⁻⁶/° C.), wherein the high temperature CTE denotes the CTE of the molding compound 108 when the withstanding temperature of the molding compound 108 is equal to or higher than the glass transition temperature of the molding compound 108, wherein the glass transition temperature of the molding compound 108 roughly ranges between 120 and 160° C.

Since the molding compound have different CTE in low temperature and in high temperature, the properties of the molding compound in low temperature (lower than the glass transition temperature of the molding compound) and in high temperature (higher than the glass transition temperature of the molding compound) also vary. Nevertheless, the molding compound 108 of the present embodiment of the invention still can be smoothly interposed between the semiconductor device 104 and the substrate 102 no matter the molding compound 108 is in a low temperature environment, during a transitional process from low temperature to high temperature, or in a high temperature environment.

The molding compound 108 of the semiconductor package 100 can possess only one, a part or all of the above properties (including the proportion of the fillers 120, the sizes of the fillers 120, the spiral flow length, the gelatin time, the low temperature CTE and the high temperature CTE of the molding compound 108), so that the space between the semiconductor device 104 and the substrate 102 is filled with the molding compound 108. The actual application of the abovementioned properties of the molding compound 108 can be determined to fit the needs in the design of the semiconductor package 100, and the present embodiment of the invention does not impose further restrictions.

Referring to Table 1 and Table 2. Table 1 illustrates the properties of the molding compound in 9 groups of semiconductor packages. Table 2 illustrates the testing results regarding the reliability, the shrinkage rate, as well as the mold voids and the warpage of solidified molding compound for the semiconductor packages of Table 1.

As indicated in group 1 to groups 6 of Table 1 and Table 2, when the fillers 120 amount to roughly between 85-89% of the molding compound 108, the sizes of fillers 120 range roughly between 18 μm and 23 μm, the spiral flow length of the molding compound roughly ranges between 120 and 160 centimeters (cm), the gelatin time of the molding compound ranges between 40 and 60 seconds, the low temperature CTE of the molding compound roughly ranges between 8 and 10 (10⁻⁶/° C.), and the high temperature CTE of the molding compound roughly ranges between 33 and 43 (10⁻⁶/° C.), the semiconductor package passes the quality assurance in terms of shrinkage rate as well as mold voids, warpage, co-planarity and reliability of solidified molding compound. The remaining groups still have problems with the mold voids and reliability test, and cannot be accepted for production.

TABLE 1

| | | | Spiral | | Low | High | Glass |
|---|---|---|---|---|---|---|---|
| | Filler | Filler | Flow | Gelatin | Temperature | Temperature | Transition |
| | Percentage | Size | Length | Time | CTE | CTE | Temperature |
| Group | (%) | (μm) | (cm) | (sec) | (10⁻⁶/° C.) | (10⁻⁶/° C.) | (° C.) |
| 1 | 88.5 | 20 | 120 | 42 | 8 | 33 | 130 |
| 2 | 85 | 20 | 140 | 45 | 10 | 42 | 135 |
| 3 | 88 | 20 | 120 | 50 | 9 | 40 | 145 |
| 4 | 88 | 20 | 130 | 50 | 8 | 43 | 155 |
| 5 | 88 | 20 | 140 | 60 | 9 | 42 | 160 |
| 6 | 88 | 20 | 160 | 55 | 8 | 33 | 120 |
| 7 | 88 | 25 | 110 | 35 | 7.8 | 33 | 130 |
| 8 | 86 | 20 | 165 | 50 | 10 | 38 | 135 |
| 9 | 80 | 20 | 155 | 50 | 16 | 60 | 185 |

TABLE 2

| | Shrinkage | Mold Voids | | | | | | |
|---|---|---|---|---|---|---|---|---|
| | Rate | Of Molding | Warpage | Co-planarity | Reliability Test | | | |
| Group | (%) | Compound | (mm) | (mil) | MSL3a | MSL3 | TCT | HAST |
| 1 | 0.13 | Pass | 3 | 2.7 | Pass | Pass | Pass | Pass |
| 2 | 0.17 | Pass | 4 | 2 | Pass | Pass | Pass | Pass |
| 3 | 0.14 | Pass | 2.5 | 1.5 | Pass | Pass | Pass | Pass |
| 4 | 0.14 | Pass | 2 | 1.2 | Pass | Pass | Pass | Pass |
| 5 | 0.15 | Pass | 3.5 | 2.2 | Pass | Pass | Pass | Pass |
| 6 | 0.08 | Pass | 2.5 | 2.6 | Pass | Pass | Pass | Pass |
| 7 | 0.13 | NG | 3.5 | 2.4 | Pass | Pass | Pass | Pass |
| 8 | 0.07 | NG | 5.2 | 3 | Pass | Pass | Pass | Pass |
| 9 | 0.18 | Pass | 3.6 | 2.4 | NG | Pass | Pass | Pass |

According to the semiconductor package disclosed in the above embodiments of the invention, a molding compound with high bonding strength is interposed between the semiconductor device and the substrate, the molding compound, hence increasing the bonding strength between the semiconductor device and the substrate.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package, comprising:
a substrate having a first surface and a second surface opposite to the first surface;
a semiconductor device disposed on the first surface;
a plurality of element contacts which electrically connects the substrate and the semiconductor device;
a molding compound which encapsulates the semiconductor device, wherein a portion of the molding compound is located between the semiconductor device and the first surface, the molding compound comprises a plurality of fillers which amounts to 85-89% of the molding compound, and the sizes of the fillers range between 18 and 23 micrometers (μm); and
a plurality of substrate contacts formed on the second surface.

2. The semiconductor package according to claim 1, wherein the spiral flow length of the molding compound ranges between 120 and 160 centimeters (cm).

3. The semiconductor package according to claim 1, wherein the gelatin time of the molding compound ranges between 40 and 60 seconds.

4. The semiconductor package according to claim 1, wherein the glass transition temperature of the molding compound substantially ranges between 120 and 160° C.

5. The semiconductor package according to claim 1, wherein the low temperature coefficient of thermal expansion (CTE) of the molding compound ranges between 8 and 10 (10⁻⁶/° C.).

6. The semiconductor package according to claim 1, wherein the high temperature CTE of the molding compound ranges between 33 and 43 (10⁻⁶/° C.).

7. A semiconductor package, comprising:
a substrate having a first surface and a second surface opposite to the first surface;
a semiconductor device disposed on the first surface;
a plurality of element contacts which electrically connect the substrate and the semiconductor device; and
a molding compound which encapsulates the semiconductor device, wherein a portion of the molding compound is located between the semiconductor device and the first surface, and the low temperature CTE of the molding compound ranges between 8 and 10; and
a plurality of substrate contacts formed on the second surface.

8. The semiconductor package according to claim 7, wherein the high temperature CTE of the molding compound ranges between 33 and 43.

9. The semiconductor package according to claim 7, wherein the spiral flow length of the molding compound ranges between 120 and 160 centimeters (cm).

10. The semiconductor package according to claim 7, wherein the gelatin time of the molding compound ranges between 40 and 60 seconds.

11. The semiconductor package according to claim 7, wherein the glass transition temperature of the molding compound substantially ranges between 120 and 160° C.

12. A semiconductor package, comprising:
a substrate having a first surface and a second surface opposite to the first surface;
a semiconductor device disposed on the first surface;
a plurality of element contacts which electrically connects the substrate and the semiconductor device;
a molding compound which directly contacts and encapsulates the semiconductor device and the element contacts, wherein the molding compound comprises a plurality of fillers which amounts to 85-89% of the molding compound, and the sizes of fillers range between 18 and 23 μm; and
a plurality of substrate contacts formed on the second surface.

13. The semiconductor package according to claim 12, wherein the spiral flow length of the molding compound ranges between 120 and 160 centimeters (cm).

14. The semiconductor package according to claim 12, wherein the gelatin time of the molding compound ranges between 40 and 60 seconds.

15. The semiconductor package according to claim 12, wherein the glass transition temperature of the molding compound substantially ranges between 120 and 160° C.

16. The semiconductor package according to claim 12, wherein the low temperature coefficient of thermal expansion (CTE) of the molding compound ranges between 8 and 10 (10⁻⁶/° C.).

17. The semiconductor package according to claim 12, wherein the high temperature CTE of the molding compound ranges between 33 and 43 (10⁻⁶/° C.).

18. A semiconductor package, comprising:
a substrate having a first surface and a second surface opposite to the first surface;
a semiconductor device disposed on the first surface;
a plurality of element contacts which electrically connects the substrate and the semiconductor device; and
a molding compound which directly contacts and encapsulates the semiconductor device and the element contacts, wherein the low temperature CTE of the molding compound ranges between 8 and 10 (10⁻⁶/° C.); and
a plurality of substrate contacts formed on the second surface.

19. The semiconductor package according to claim 18, wherein the high temperature CTE of the molding compound ranges between 33 and 43 (10⁻⁶/° C.).

20. The semiconductor package according to claim 18, wherein the glass transition temperature of the molding compound substantially ranges between 120 and 160° C.
